(19) United States
(12) Patent Application Publication
(10) Pub. No.: US 2010/0237343 A1
(43) Pub. Date: Sep. 23, 2010

(54) ZnO-BASED THIN FILM AND SEMICONDUCTOR DEVICE

(75) Inventors: Ken Nakahara, Kyoto (JP); Hiroyuki Yuki, Kyoto (JP); Kentaro Tamura, Kyoto (JP); Shunsuke Akasaka, Kyoto (JP); Masashi Kawasaki, Miyagi (JP); Akira Ohmoto, Miyagi (JP); Atsushi Tsukazaki, Miyagi (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 12/675,783

(22) PCT Filed: Aug. 27, 2008
(86) PCT No.: PCT/JP2008/065269

§ 371 Date: Feb. 28, 2010

(30) Foreign Application Priority Data
Aug. 27, 2007 (JP) 2007-220186
Aug. 28, 2007 (JP) 2007-221198

(51) Int. Cl. H01L 29/22

(52) U.S. Cl. 257/43; 257/E29.094

(57) ABSTRACT

Provided are a ZnO-based thin film which is inhibited from being doped with an unintentional impurity, and a semiconductor device. The ZnO-based thin film has a main surface: which is formed of MgₓZn₁₋ₓO (0≦x<1) containing a p-type impurity; and which satisfies at least any one of the following conditions when the main surface is observed with an atomic force microscope: the density of observed hexagonal pits is not more than 5×10⁶ pits/cm²; and no depressed portion, which includes multiple microcrystalline protrusions formed in the bottom portion of the depressed portion, is found in the main surface.

### TECHNICAL FIELD

The present invention relates to a ZnO-based semiconductor device, and particularly, relates to an acceptor-doped ZnO-based thin film and a semiconductor device.

### BACKGROUND ART

A zinc oxide (ZnO)-based semiconductor has a large binding energy of its excitons, which are capable of stably existing at room temperature, and therefore ZnO has a high potential of emitting photons excellent in monochromaticity. For these reasons, the ZnO-based semiconductor has been increasingly studied for applications to: light-emitting diodes (LEDs) used as light sources such as illuminations and backlights; high-speed electron devices; and surface acoustic wave devices; and the like. When a ZnO-based semiconductor containing MgZnO is used as a P-type semiconductor, however, the ZnO-based semiconductor has a problem that difficulty in doping the ZnO-based semiconductor with an acceptor makes it difficult to obtain a P-type ZnO-based semiconductor. Technological progress has recently enabled obtaining the p-type ZnO-based semiconductor, and has proved that the p-type ZnO-based semiconductor emits light. However, this ZnO-based semiconductor has such a restriction that a special substrate made of ScAlMgO₄ has to be used (see Non-patent Documents 1 and 2, for example). Accordingly, the semiconductor industry awaits a technology for forming a p-type ZnO-based semiconductor film on a ZnO-based substrate.

Non-patent Document 1: Tsukazaki, A., et al. (2005), Japanese Journal of Applied Physics, vol. 44, p. 643. Non-patent Document 2: Tsukazaki, A., et al. (2005), Nature Materials, vol. 4, p. 42.

### DISCLOSURE OF THE INVENTION

### Problems to be Solved by the Invention

The ZnO-based semiconductor, however, is a substance in which a donor is extremely easily formed. Because the valence band of the ZnO-based semiconductor is deep, the crystal of ZnO-based semiconductor becomes unstable once holes are produced in the valence band of a ZnO-based semiconductor. Accordingly, the donor state that compensates the holes is apt to be formed. This self-compensation effect is a cause of difficulty in doping the ZnO-based semiconductor with an acceptor such as nitrogen. In many cases, the self-compensation effect is induced by a point defect which occurs due to the acceptor doping. In the ZnO film, however, the self-compensation effect takes place due to other causes as well. Specifically, the self-compensation effect occurs also due to an impurity such as silicon (Si) which is mixed into the ZnO film during the manufacturing process. For example, if the ZnO film with a rough surface is unintentionally doped with Si, doping of the ZnO film with the acceptor becomes difficult.

With the above-mentioned problems taken into consideration, an object of the present invention is to provide a ZnO-based thin film which is inhibited from being doped with an unintentional impurity, and a semiconductor device.

### Means for Solving the Problems

In order to achieve the above object, the invention according to claim 1 is a ZnO-based thin film formed of MgₓZn₁₋ₓO (0≦x<1) containing a p-type impurity, the ZnO-based thin film comprising a main surface which satisfies at least one of the following conditions when the main surface is observed with an atomic force microscope: the density of observed hexagonal pits is not more than 5×10⁶ pits/cm²; and no depressed portion, which includes a plurality of microcrystalline protrusions formed in a bottom portion of the depressed portion, is observed.

In addition, the invention according to claim 2 is the ZnO-based thin film according to claim 1, wherein the p-type impurity is nitrogen.

Additionally, the invention according to claim 3 is the ZnO-based thin film according to claim 1, wherein the MgₓZn₁₋ₓO thin film is formed by crystal growth on a ZnO substrate whose main surface on a crystal growth side has a c-plane.

Moreover, the invention according to claim 4 is the ZnO-based thin film according to claim 1, wherein each pit is a defect including a hexagonal crystal plane when viewed from above, and a cross-section of the pit looks like a funnel.

Further, the invention according to claim 5 is a semiconductor device comprising the ZnO-based thin film according to claim 1.

Furthermore, the invention according to claim 6 is a semiconductor device comprising: a ZnO-based thin film formed of MgₓZn₁₋ₓO (0≦x<1) containing a p-type impurity, the ZnO-based thin film including a main surface which satisfies at least one of the following conditions when the main surface is observed with an atomic force microscope: the density of observed hexagonal pits is not more than 5×10⁶ pits/cm²; and no depressed portion, which includes a plurality of microcrystalline protrusions formed in a bottom portion of the depressed portion, is observed; and a substrate formed of Mg_{y}Zn_{1-y}O (0≦y<1), the substrate including a substrate main surface in contact with the ZnO-based thin film, in the substrate wherein a projection axis, which is obtained by projecting a normal line of the substrate main surface on plane produced by a m-axis and a c-axis of a substrate crystal axis as its bases, inclines toward a m-axis at an angle of 3 degrees or less.

Also, the invention according to claim 7 is the semiconductor device according to claim 6, wherein a projection axis, which is obtained by projecting the normal line of the substrate main surface on plane produced by an a-axis and a c-axis of a substrate crystal axis as its bases, inclines toward an a-axis at an angle of pa degrees, a projection axis, which is obtained by projecting the normal line of the substrate main surface on plane produced by a m-axis and a c-axis of a substrate crystal axis as its bases, inclines toward the m-axis at an angle of φm degrees, and φa and φm satisfy a relationship expressed by

70≦90−(180/Π)arctan {tan(Πφa/180)/tan(Πφm/180)}≦110.

### EFFECTS OF THE INVENTION

The present invention can provide a ZnO-based thin film which is inhibited from being doped with an unintentional impurity, and a semiconductor device.

### BRIEF DESCRIPTION OF THE DRAWINGS

FIG. 1 is a schematic diagram showing a configuration of a semiconductor device according to an embodiment of the present invention.

FIG. 2 are schematic diagrams showing an example of a thin film forming apparatus.

FIG. 3 are diagrams showing properties of the semiconductor device according to the embodiment of the present invention. FIG. 3(a) is a graph showing an impurity concentration. FIG. 3(b) is a diagram showing a condition of a main surface of the semiconductor device.

FIG. 4 are diagrams showing properties of a comparative example. FIG. 4(a) is a graph showing an impurity concentration. FIG. 4(b) is a diagram showing a condition of a main surface of the semiconductor device. FIG. 4(c) is a cross-sectional view of the condition of the main surface shown in FIG. 4(b).

FIG. 5 are schematic diagrams used to explain a CV measurement. FIG. 5(a) is a top view of a sample of a measurement object. FIG. 5(b) is a side view of the sample of the measurement object.

FIG. 6 is a magnified view of FIG. 4(b).

FIG. 7 are diagrams showing properties of a semiconductor device having a large number of pits produced therein. FIG. 7(a) is a graph showing an impurity concentration. FIG. 7(b) is a diagram showing a condition of a main surface of the semiconductor device. FIG. 7(c) is a magnified view of FIG. 7(b).

FIG. 8 are diagrams showing other properties of the semiconductor device according to the embodiment of the present invention. FIG. 8(a) is a graph showing an impurity concentration. FIG. 8(b) is a diagram showing a condition of a main surface of the semiconductor device. FIG. 8(c) is a magnified view of FIG. 8(b).

FIG. 9 are diagrams showing: the conditions of the main surfaces of the semiconductor device according to the embodiment of the present invention and the comparative example. FIG. 9(a) is a diagram showing the condition of the main surface of the sample shown in FIG. 8. FIG. 9(b) is a magnified view of FIG. 9(a). FIG. 9(c) is a diagram showing the condition of the main surface of the sample shown in FIG. 6. FIG. 9(d) is a magnified view of FIG. 9(c).

FIG. 10 is a diagram to explain pits.

FIG. 11 is a graph showing a relationship between a Si concentration in an interface and a Si concentration in a film.

FIG. 12 is a diagram showing a relationship between a RMS on the surface of a film and a concentration of Si contaminant.

FIG. 13 is a diagram showing a relationship between a PV on the surface of the film and the concentration of Si contaminant.

FIG. 14 is a diagram used to explain the RMS and the PV which are indices of the flatness of the film.

FIG. 15 are diagrams showing AFM images representing typical patterns of a surface shape of the film.

FIG. 16 are diagrams each showing classification of surface shapes depending on their surface roughness.

FIG. 17 is a schematic diagram used to explain a hexagonal crystal structure.

FIG. 18 is a diagram showing a relationship among a normal to a main surface of a substrate and c-axis, m-axis and a-axis which are crystal axes of the substrate.

FIG. 19 is a schematic diagram used to explain how the normal line of a ZnO-based substrate main surface inclines from a C-plane.

FIG. 20 are schematic diagrams each showing a relationship between step edges and the m-axis. FIG. 20(a) shows the case where a plane normal inclines in the positive direction of the a-axis. FIG. 20(b) shows the case where the plane normal inclines in the negative direction of the a-axis.

FIG. 21 are schematic diagrams used to explain how the plane normal to the substrate main surface inclines. FIG. 21(a) shows the plane normal which does not incline at all. FIG. 21(b) shows the plane normal which inclines only toward the m-axis. FIG. 21(c) shows a condition of the main surface shown in FIG. 21(b). FIG. 21(d) shows a relationship between the substrate main surface and the C-plane.

FIG. 22 are diagrams each showing a condition of the main surface of the semiconductor layer formed on the substrate which inclines from the C-plane. FIG. 22(a) shows the case where the inclining angle is 1.5°. FIG. 22(b) shows the case where the inclining angle is 3.5°.

FIG. 23 are schematic diagrams used to explain how the plane normal to the substrate main surface inclines. FIG. 23(a) shows the plane normal which inclines toward both the m-axis and the a-axis. FIG. 23(b) shows a condition of the main surface shown in FIG. 23(a).

FIG. 24 are diagrams showing how different conditions of the substrate main surfaces of the substrates become with the change in the angle θs between the step edges and the direction of the m-axis when the substrates have different off angles between the plane normal to the substrate main surface and the a-axis. FIG. 24(a) shows the case where the angle θs is 85°. FIG. 24(b) shows the case where the angle θs is 78°. FIG. 24(c) shows the case where the angle θs is 65°.

FIG. 25 is a diagram showing an example of a ZnO-based semiconductor device configured by using the Zn-based thin film according to the present invention.

FIG. 26 are diagrams respectively showing a PL light emission and an EL light emission of the ZnO-based semiconductor device shown in FIG. 25.

### EXPLANATION OF REFERENCE NUMERALS

1 . . . substrate
2 . . . semiconductor layer
10 . . . thin film forming apparatus
11 . . . substrate main surface
21 . . . main surface
110 . . . holder
120 . . . cell
130 . . . cell
131 . . . electric discharge tube
132 . . . high-frequency coil
140 . . . cell
201 . . . pit
202 . . . depressed portion
203 . . . microcrystal

### BEST MODES FOR CARRYING OUT THE INVENTION

Next, referring to the drawings, descriptions will be provided for an embodiment of the present invention. Throughout the following drawings, the same or similar component parts are denoted by the same or similar reference numerals. However, note that: the drawings are schematic representations; and a relationship between the thickness and plan dimension of each layer, a ratio among layers, and the like in each drawing are accordingly different from the real ones. For this reason, the concrete thickness and dimension of each layer shall be understood with the following descriptions taken into consideration. It is a matter of course that a dimensional relationship among layers and a ratio among thicknesses of the respective layers are different among the drawings.

Furthermore, the embodiment will be hereinbelow shown to exemplify apparatuses for, and method of, embodying the technical idea of the present invention. However, the technical idea of the present invention is not intended to limit materials, shapes, structures, placements or the like of the component parts to what will be described hereinbelow. The technical idea of the present invention can be variously modified within the scope of claims.

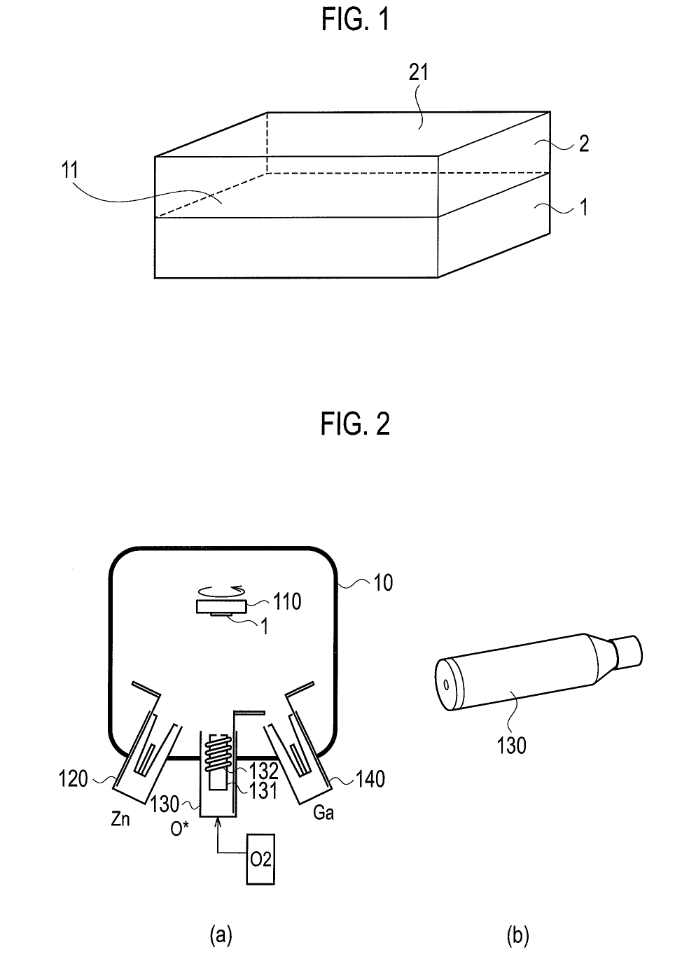

As shown in FIG. 1, a semiconductor device according to the embodiment of the present invention includes a semiconductor layer 2 which is made of MgₓZn₁₋ₓO (0≦x<1) containing a p-type impurity. The semiconductor layer 2 is a ZnO-based thin film which satisfies at least one of the following conditions when a main surface 21 of the semiconductor layer 2 is observed with an atomic force microscope (AFM). One condition is that the density of observable hexagonal pits in the main surface 21 of the semiconductor surface 2 shall be equal to or less than 5×10⁶ pits/cm². The other condition is that no depressed portion, which includes multiple microcrystalline protrusions produced in the bottom portion of the depressed portion, shall be found in the main surface 21 of the semiconductor layer 2.

The p-type impurity contained in the semiconductor layer 2 is an acceptor impurity with which the semiconductor layer 2 is acceptor-doped. For example, nitrogen (N), copper (Cu), phosphorus (P) and the like may be used as the p-type impurity. The semiconductor layer 2 is placed on a substrate main surface 11 of a substrate 1. For example, Mg_{y}Zn_{1-y}O (0≦y<1) and the like may be used for the substrate 1. The crystal structure of each of the substrate 1 and the semiconductor layer 2 is a hexagonal system. The substrate main surface 11 is the c-plane. For this reason, the main surface 21 of the semiconductor layer 2, which is formed by growing MgₓZn₁₋ₓO on the substrate main surface 11, is the c-plane.

As already described, the ZnO-based semiconductor film exhibits a strong self-compensation effect. For this reason, for the purpose of making the semiconductor layer 2 of a P-type semiconductor by acceptor doping, the semiconductor device needs to be formed while unintentional impurities such as Si, which induce the self-compensation effect, are inhibited from being mixed into the acceptor dopant. For example, in a case where the molecular beam epitaxy (MBE) method is used to form a ZnO film, it is likely that, as described below, the ZnO film may be doped with unintentional donor impurities.

Currently, a commonly-used method for forming a high-impurity ZnO-based semiconductor film, including a high-impurity MgₓZn₁₋ₓO film, is the MBE method. The MBE method uses elements as its raw materials, whereas the metal organic chemical vapor deposition (MOCVD) method uses a chemical compound as its raw material. For this reason, the MBE method allows the purity of its raw materials to be higher than the MOCVD method allows the purity of its raw material.

FIG. 2 show an example of a thin film forming apparatus which is used for the MBE method. A thin film forming apparatus 10 shown in FIG. 2(a) includes: a holder 110 on which to place the substrate 1; and cells 120, 130, 140 from which to supply the respective materials for the thin film to be formed. In the example shown in FIG. 2(a), zinc (Zn) is supplied from the cell 120, and gallium (Ga) is supplied from the cell 140. The cell 130 is a radical generator, and is used in a case where the MBE method is used to grow a chemical compound crystal which contains a gaseous element, such as a ZnO film and a GaN film. The radical generator is built as a structure in which: a high-frequency coil 132 is wound around the outer circumference of a discharge tube 131 usually made of PBN (pyrolytic boron nitride) or quartz; and the high-frequency coil 132 is connected to a high-frequency power supply (not illustrated). In the example shown in FIG. 2(a), the high-frequency coil 132 applies a high-frequency voltage (electric field) to oxygen (O₂) which is supplied to the inside of the cell 130. Thereby, a plasma is generated, and radical particles (O*) are thus supplied from the cell 130. FIG. 2(b) shows the radical generator 130 which uses the discharge tube 131 made of quartz.

The use of the plasma is desirable as a method of increasing the chemical activation efficiency. However, the use of plasma cause a sputtering phenomenon in which: the plasma particles collide against the nearly-located members of the thin film forming apparatus; and the plasma particles accordingly dislodge constituent elements from the surfaces of the members. This sputtering phenomenon raises the likelihood that the thin film, which is formed on the substrate 1, may be unintentionally doped with the constituent elements thus dislodged. In a case where an oxide such as a ZnO film is grown on the substrate 1, oxygen is used as the material gas. For this reason, PBN which is deteriorated through oxidation is not used for the discharge tube 131. Instead, quartz is used for the discharge tube 131. The reason why quartz is used for the discharge tube 131 is that no insulating material whose purity is higher than that of quartz is available. Nevertheless, quartz naturally contains Si, aluminum (Al), boron (B) and the like as impurities. For this reason, it is likely that: these impurities may be dislodged from the surface of quartz, which is used for the discharge tube 131, through the sputtering phenomenon; and the thin film, which is intended to be grown on the substrate 1, may be accordingly doped with the impurities thus dislodged.

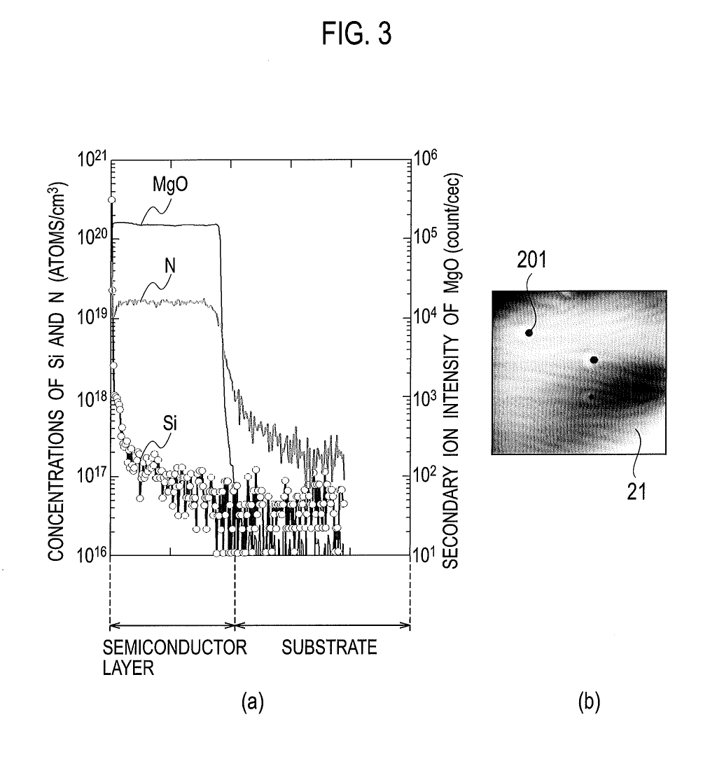

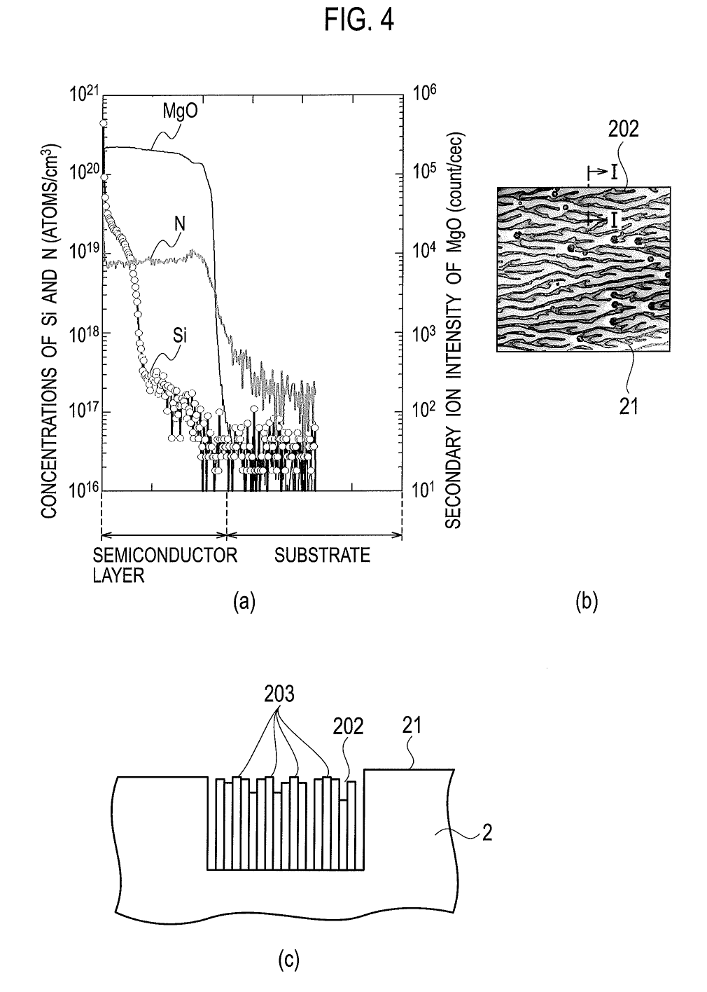

With regard to Si, nitrogen (N) and MgO contained in a semiconductor device which includes the semiconductor layer 2 doped with nitrogen as an acceptor, FIG. 3(a) shows examples of the concentrations of Si and nitrogen (N) as well as the secondary ion intensity of MgO. The semiconductor device, which exhibits the properties shown in FIG. 3(a), will be hereinafter referred to as “Sample A.” FIG. 3(b) shows a condition of the main surface 21 of Sample A. For the comparison purpose, FIG. 4(a) shows examples of the concentrations of Si and nitrogen as well as the secondary ion intensity of MgO with regard to Si, nitrogen and MgO contained in a semiconductor device (hereinafter referred to as “Sample B”) including the semiconductor layer 2 whose main surface 21 has a condition as shown in FIG. 4(b). FIGS. 3(b) and 4(b) are diagrams showing the conditions of the main surfaces 21 in an area of 20 μm² which were observed with an atomic force microscope, respectively. Note that the concentration of Si was measured by secondary ion mass spectrometry (SIMS) (the SIMS was used to measure the concentration of Si in the following cases as well).

Comparison between FIGS. 3(a) and 4(a) makes it apparent that the concentration of Si is higher in Sample B than in Sample A. In the case of Sample A, Si exists only in the main surface 21 of the semiconductor layer 2 and its vicinity as shown in FIG. 3(a), because the lower limit of the concentration measurement is 1×10¹⁷ atoms/cm³. However, the SIMS is a measurement method which is poor at identifying the chemical constitution in the uppermost surface of any object. In this context, it is likely that the measurement value of the concentration of Si in the uppermost surface of the semiconductor layer 2 may be inaccurate. In the case of Sample B, however, Si spreads to a depth which is almost equal to a half of the thickness of the semiconductor layer 2 as shown in FIG. 4(a). In addition, the concentration of nitrogen is higher in Sample A shown in FIG. 3(a).

In this respect, as apparent from comparison between FIGS. 3(b) and 4(b), the main surface 21 of Sample A is flat, whereas the main surface 21 of Sample B is rough. Only several pits 201 are produced in the main surface 21 of Sample A. In contrast, however, multiple depressed portions 202 are produced in the main surface 21 of Sample B. FIG. 4(c) shows a cross-sectional view of one depressed portion 202 taken along the I-I line of FIG. 4(b). As shown in FIG. 4(c), multiple microcrystals 203 are produced in the bottom portion of the depressed portion 202. In other words, the main surface 21 of the sample B is characterized in that: flat portions are formed into multiple stripe-shape islands; and depressed portions 202 each including a small aggregation of microcrystals exist between neighboring islands. On the other hand, the flat portions of the main surface 21 of Sample A looks like stripes, but no aggregation of microcrystals exists in the main surface 21 of Sample A.

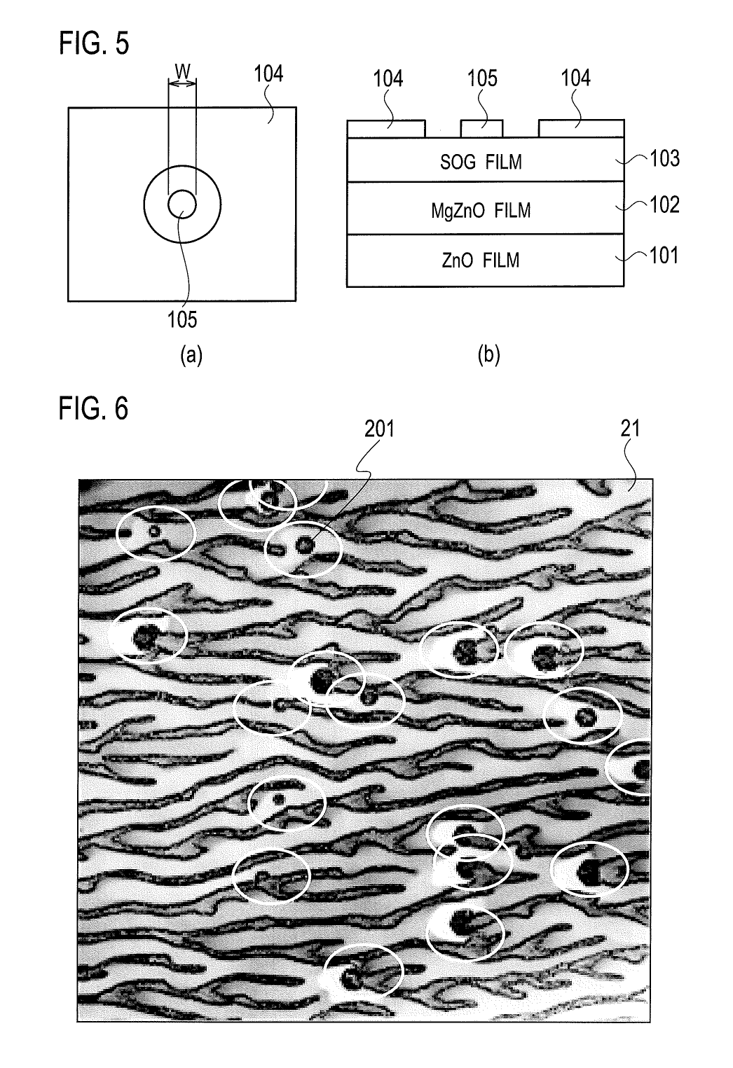

For each of the film whose main surface was as shown in FIG. 3 and the film whose main surface was as shown in FIG. 4, the CV measurement was carried out with the film being incorporated into a MOS (metal Oxide Semiconductor) structure. As a result of the measurement, in the case of the film whose main surface was as shown in FIG. 3, the concentration difference N_{D}-N_{A} between the donor concentration N_{D} and the acceptor concentration N_{A} was approximately 1×10¹⁶ atoms/cm³. On the other hand, in the case of the film whose main surface was as shown in FIG. 4, the concentration difference N_{D}-N_{A} was approximately 5×10¹⁷ atoms/cm³. Judging from this, it is apparent that Si worked in a way that Si increased the amount of donors in the semiconductor layer, although the activation yield of Si was lower than that of the III group element such as boron (B), Al and Ga. Note that, as shown in FIG. 5, this CV measurement was achieved by: stacking a ZnO film 101, a MgZnO film 102 and a SOG (Spin on Glass) film 103 one on another in this sequence; and subsequently measuring the electric current and voltage between a column-shaped electrode 105 placed on the SOG film 103 and an electrode 104 placed on the SOG film 103 with a space being interposed between the electrode 104 and the electrode 105. A structure, such as that obtained by stacking Al and titanium (Ti), may be used for the electrodes 104 and 105. The diameter W of the electrode 105 is, for example, 100 μm.

As described above, the comparison between Sample A shown in FIG. 3 and Sample B shown in FIG. 4 makes it apparent that, in the case where the main surface 21 was rough, the amount of Si with which the semiconductor layer 2 was unintentionally doped became larger, and the amount of nitrogen as the acceptor with which the semiconductor layer 2 needed to be doped became smaller. Therefore, as the surface condition of the main surface 21 becomes flatter, the semiconductor layer 2 is more effectively inhibited from being doped with unintentional impurities such as Si. In other words, when the condition of the main surface 21 of the semiconductor layer 2 becomes as shown in FIG. 3(b), the semiconductor layer 2 can be easily made of the p-type semiconductor by doping the semiconductor layer 2 with the p-type impurity as the acceptor such as nitrogen while inhibiting the semiconductor layer 2 from being unintentionally doped with Si. On the other hand, when the condition of the main surface 21 of the semiconductor layer 2 becomes as shown in FIG. 4(b), the amount of Si with which the semiconductor layer 2 is unintentionally doped becomes larger. This makes it difficult to form the semiconductor layer 2 of the p-type semiconductor by doping the semiconductor layer 2 with the p-type impurity as the acceptor such as nitrogen.

FIG. 6 shows a magnified view of a condition of the main surface 21 shown in FIG. 4(b). As shown in FIG. 6, 19 pits 201 exist in the area of 20 μm². In other words, the density of pits is 4.75×10⁶ pits/cm². In this case, the semiconductor layer 2 barely satisfies the condition that the density of pits 201 in the main surface 21 should be equal to or less than 5×10⁶ pits/cm². However, the semiconductor layer 2 cannot satisfy the other condition that no depressed portion 202, which includes the multiple microcrystals 203 formed in the bottom portion of the depressed portion 202, should be observed.

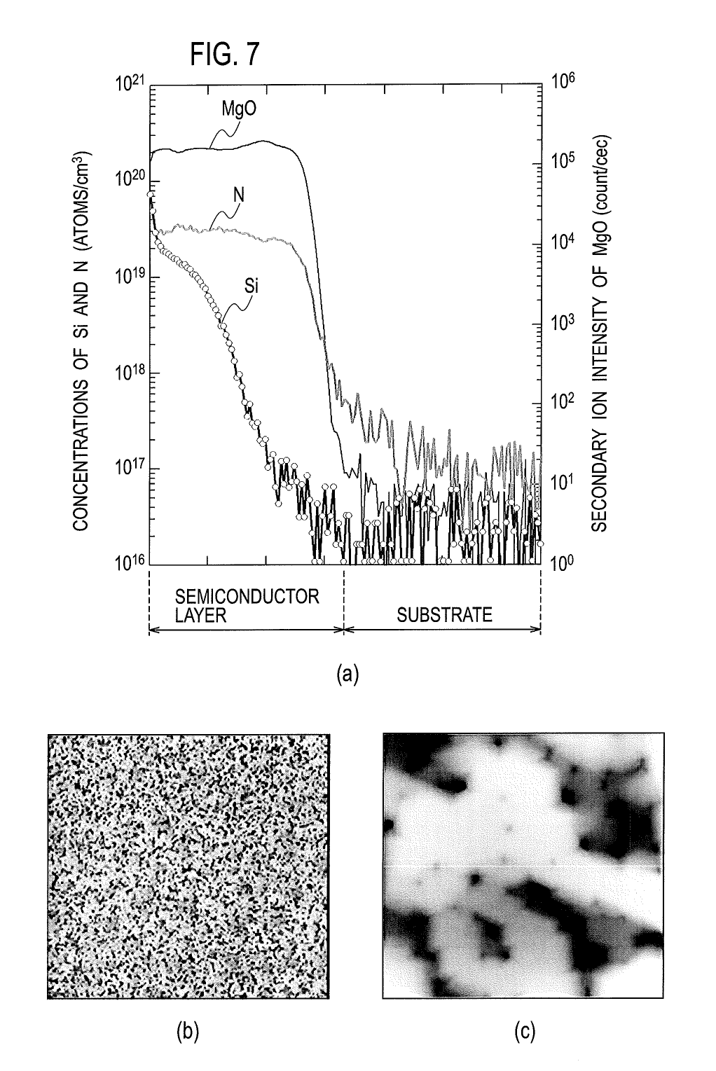

FIG. 7 show an example of a semiconductor device in which multiple pits 201 exist in the main surface 21. FIG. 7(a) shows the concentrations of Si and nitrogen contained in the semiconductor device as well as the secondary ion intensity of MgO contained in the same semiconductor device. FIG. 7(b) is a diagram showing a condition of the main surface 21 in an area of 20 μm² which was observed with the atomic force microscope. FIG. 7(c) is a view showing a condition of the main surface 21 in an area of 1 μm² by magnifying a part of the main surface 21 shown in FIG. 7(b).

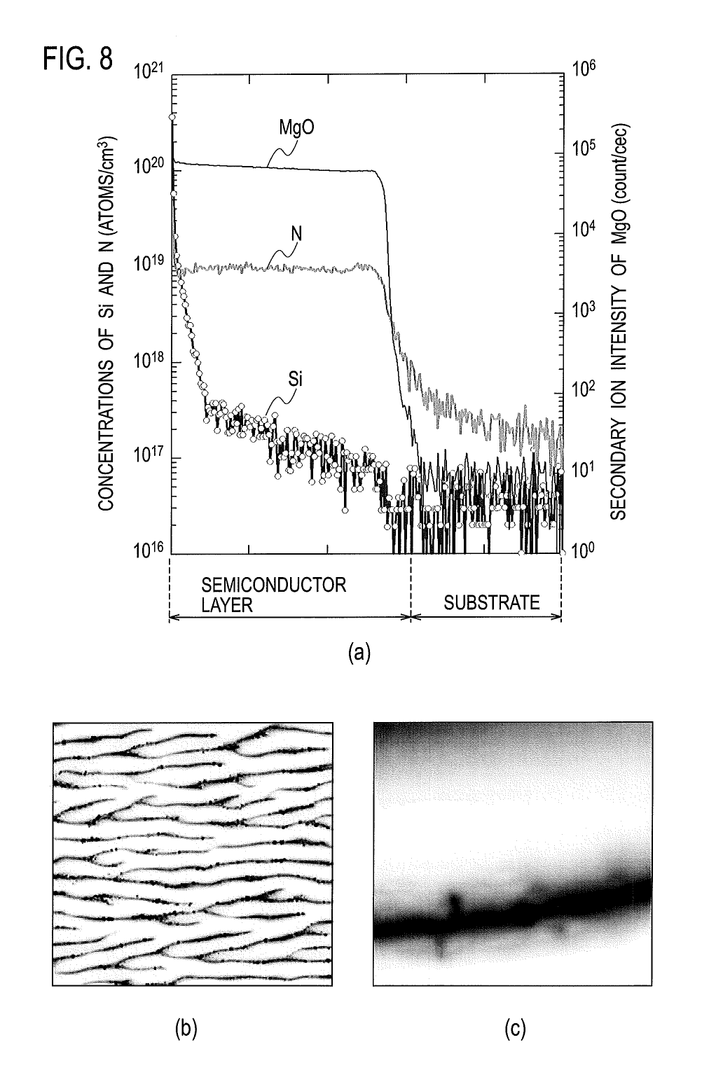

FIG. 8 show an example of a sample (hereinafter referred to as “Sample C”) in which the main surface 21 was inhibited from being unintentionally doped with Si to the utmost limit. FIG. 8(a) shows the concentrations of Si and nitrogen contained in the semiconductor device as well as the secondary ion intensity of MgO contained in the same semiconductor device. FIG. 8(b) is a diagram showing a condition of the main surface 21 in an area of 20 μm² which was seen when the main surface 21 was observed with the atomic force microscope. FIG. 8(c) is a view of showing a condition of the main surface 21 in an area of 20 μm² by magnifying a part of the main surface 21 shown in FIG. 8(b). As shown in FIGS. 8(b) and 8(c), flat portions of the main surface 21 of Sample C are shaped like stripes, which are divided by depressed portions, as in the case of Sample B. However, the number of pits, which are as large as those in the main surface 21 of Sample B shown in FIG. 6, is not large in the main surface 21 of Sample C.

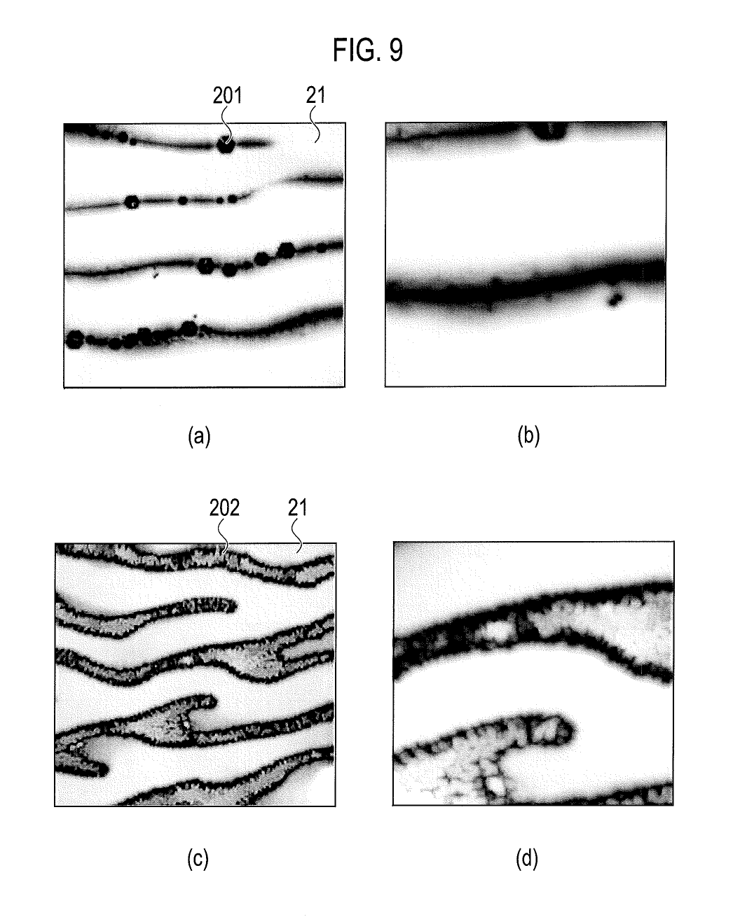

FIG. 9 show a comparison between Sample C in which the semiconductor layer 2 was doped with no Si, which is shown in FIG. 8, and Sample B in which the semiconductor layer 2 was unintentionally doped with Si, which is shown in FIG. 6. FIG. 9(a) is a diagram showing a condition of the main surface 21 of Sample C in an area of 5 μm²; and FIG. 9(b) is a diagram showing the condition of the main surface 21 in an area of 2 μm² by magnifying the main surface 21 of Sample C shown in FIG. 9(a). FIG. 9(c) is a diagram showing a condition of the main surface 21 of Sample B in an area of 5 μm²; and FIG. 9(d) is a diagram showing the condition of the main surface 21 of Sample B in an area of 2 μm² by magnifying the main surface 21 shown in FIG. 9(c). The comparison between FIGS. 9(b) and 9(d) shows that: in Sample B, depressed portions 202 each constituting an aggregation of microcrystals are produced between flat portions of the stripe-shaped islands; and in contrast, in Sample C, although the flat portions are formed into stripe-shaped islands, no aggregation of microcrystals exists in flat portions.

Note that: the concentration of Si is higher in Sample C shown in FIG. 8 than in Sample A shown in FIG. 3; and from a viewpoint that the semiconductor layer 2 should be inhibited from being unintentionally doped with Si, Sample C is accordingly not a semiconductor device which is the most suitable for the mass production. The condition of the main surface 21 of the sample C is merely a condition of the main surface 21 of the semiconductor layer 2 which is inhibited from being unintentionally doped with Si to the utmost limit. Sample A is more desirable than Sample C with the condition of the main surface 21 taken into consideration.

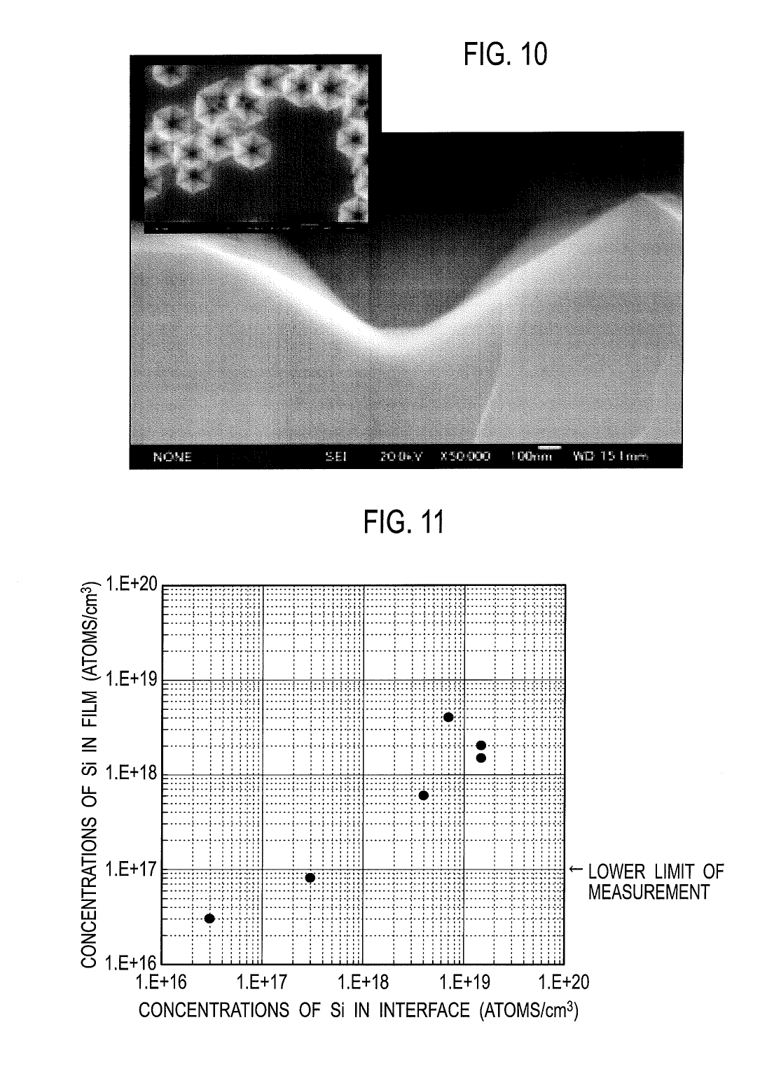

FIG. 10 show magnified views of pits 201. The pits 201 shown in FIG. 10 were slightly etched with diluted hydrochloric acid for the purpose of making the pits 201 more visible. FIG. 10 includes a view of a cross section of one pit 201 which is magnified by 50,000 times, and a diagram inserted in FIG. 10 is a view of the top surfaces of the respective pits 201 which are magnified by 10,000 times. As shown in FIG. 10, each pit 201 looks like a hexagon when the pit 201 is looked down at from a height, and it is apparent that each 201 includes a crystal plane. In addition, the cross section of each pit 201 is shaped like a funnel. As the depression of the pit 201 becomes deeper, the shape of the pit 201 which is looked down at from a height becomes larger.

As described above, for the purpose of inhibiting the semiconductor layer 2 from being unintentionally doped with Si, the main surface 21 of the semiconductor layer 2 needs to satisfy at least one of the following conditions when the main surface 21 of the semiconductor layer 2 is observed with the atomic force microscope. The first condition is that the density of observable pits 201 in the main surface 21 should be not more than 5×10⁶ pits/cm². The second condition is that no depressed portion 202, which includes multiple microcrystals 203 formed in the bottom portion of the depressed portion 202, shall be observed.

FIG. 11 shows a relationship between a Si concentration in an interface of the semiconductor layer 2 and a concentration of Si in the film of the semiconductor layer 2. As shown in FIG. 11, the concentration of Si in the film is in proportion to the concentration of Si in the interface. From this, it can be learned that some portion of Si existing in the interface was diffused into the film. In this context, the semiconductor layer 2 should be prevented from being doped with Si. Note that: the lower limit of measurement of the concentration of Si is approximately 1×10¹⁷ atoms/cm³; and measurements values lower than the lower limit, which are shown in FIG. 11, are unreliable.

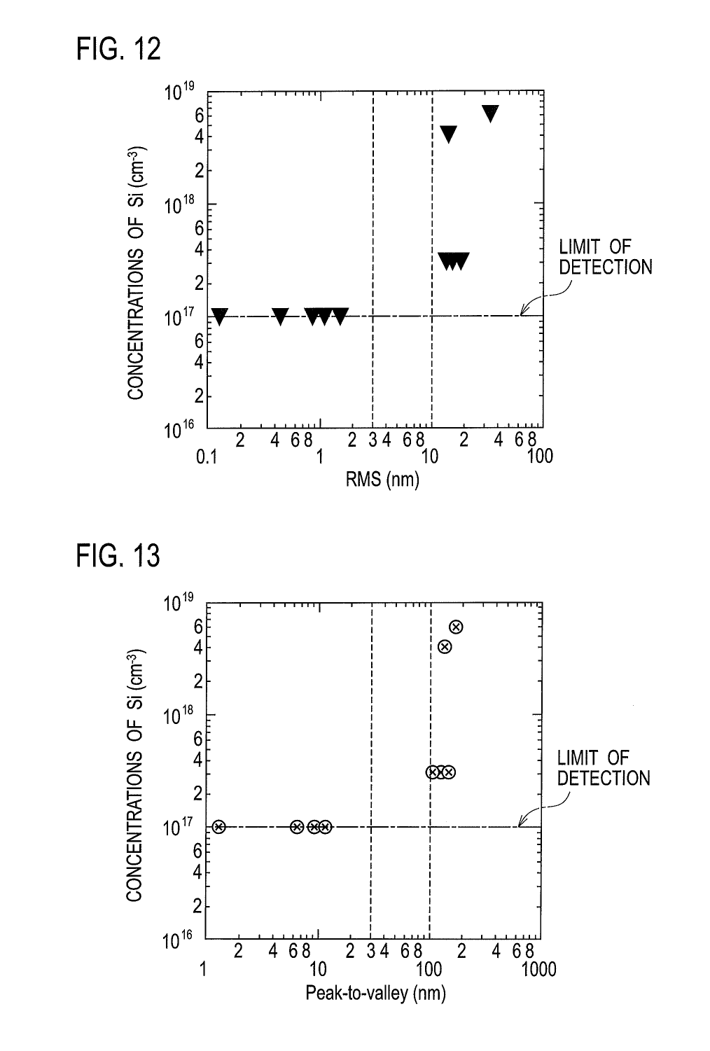

Next, FIGS. 12 and 13 show a detailed relationship between a flatness of the surface of a film made of a ZnO-based semiconductor and the concentration of Si contaminant. FIGS. 12 and 13 are graphs representing measurements made with respect to different indices of a roughness of the surface of a nitrogen-doped MgZnO thin film (the semiconductor layer 2) whose crystal was grown on the ZnO substrate (the substrate 1). Descriptions will be provided for an example of a method of forming the nitrogen-doped MgZnO thin film on the ZnO substrate.

The ZnO substrate, whose +C-plane is used as the crystal growth surface, is etched with diluted hydrochloric acid, and is subsequently rinsed with pure water. Thereafter, the resultant ZnO substrate is dried with dry nitrogen. Afterward, the ZnO substrate is set on the substrate holder, and the thus-set ZnO substrate is introduced in a growth chamber in the MBE apparatus through a load-lock chamber After that, the temperature of the substrate is raised to 850° C., and the substrate is thus heated in vacuum of approximately 1×10⁻⁷ Pa for 30 minutes. Thereby, the substrate is thermally cleaned. Subsequently, the temperature of the substrate is decreased to 750° C., and plasma is produced while supplying a NO gas to the nitrogen radical cell and an O₂ gas to the oxygen radical cell. The thus-produced plasma is supplied to the growth chamber along with Mg and Zn whose amounts are beforehand controlled in order to cause the MgZnO thin film to have a desired composition. Thereby, the nitrogen-doped MgZnO thin film is produced.

In this respect, it is already known that the growth temperature needs to be raised to 750° C. or higher in order to form the MgZnO thin film flatly (see Japanese Patent Application No. 2007-27182). For example, when the growth temperature is set at 800° C., it is possible to obtain a flat MgZnO thin film. In contrast, when the growth temperature is set at a lower temperature such as 600° C., the surface of a produced MgZnO thin film becomes rougher as shown in FIG. 4(b).

With this taken into consideration, the crystal of the MgZnO thin film was grown at each of variously-changed growth temperatures. FIGS. 12 and 13 show graphs drawn by expressing as numeral values the roughnesses of the MgZnO thin films thus produced, and by measuring the concentrations of Si contaminant therein by the secondary ion mass spectrometry. First of all, descriptions will be provided for FIG. 12. In the graph shown in FIG. 12, its vertical axis represents the concentration of Si (cm⁻³) of each thin film, and its horizontal axis represents the RMS (unit:nm) of the surface of the film.

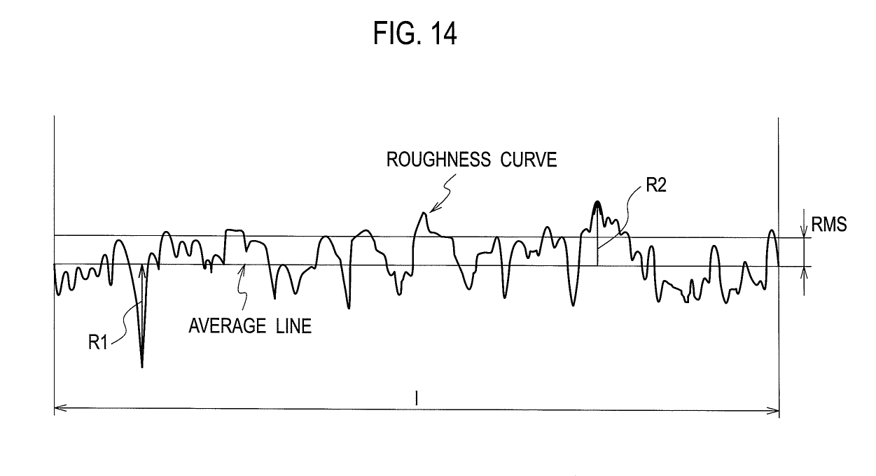

The root square mean roughness RMS is found from a roughness curve representing measured roughnesses shown in FIG. 14. The roughness curve represents the magnitudes of roughnesses of a film surface observed, for example, as shown in the AFM images of FIGS. 3(b) and 4(b), and measured at predetermined sampling points, together with the average of these roughness magnitudes. The root square mean roughness RMS refers to the square-root of a mean value of the sum of a squared deviation f(x) of the measurement curve from the average line over a portion extracted from the roughness curve by a reference length 1. In short, the RMS is expressed with

RMS={(1/l)×∫(f(x))²dx}^{1/2} (over the interval[0,l])

where the reference length is denoted by l. Note that: the parameters of the surface roughness, such as the root mean square RMS, are specified in the JIS standards; and these parameters were used herein.

As learned from FIG. 12, the concentration of Si contaminant abruptly increases after the RMS exceeds 10 nm. Judging from this, as long as the root mean square roughness RMS of the MgₓZn₁₋ₓO thin film is not more than 10 nm, the concentration of Si contaminant is equal to or less than the detection limit as also clear from FIG. 11. On the basis of this, the aforementioned flatness can be used as a reference.

When data gathering around 10¹⁷ cm⁻³ equal to or less than the detection limit of the concentration of Si contaminant are classified into a group, the RMS of the data are all distributed within a region of 3 nm or less. Accordingly, it is desirable to set the RMS of the film at 3 nm or less when a more strict reference is to be set up for the film.

On the other hand, FIG. 13 show a measured PV (Peak to Valley) representing the maximum range in roughness. The PV represents a maximum value of the deviation of the measurement points on the roughness curve from the average line in the roughness curve as shown in FIG. 14. For example, the PV means a deviation range from the average line whose absolute value is the largest among those of the deviation ranges such as R1 and R2. In short, the PV represents the maximum range of the roughness.

As learned from FIG. 13, the concentration of Si contaminant abruptly increases after the PV of the film exceeds 100 nm. On the other hand, when PV≦100 nm, the concentration of Si remains unchanged around 10¹⁷ cm⁻³ equal to or less than the detection limit of the Si concentration. From this, it is learned that this PV can be used as a reference for the flatness of the film. Furthermore, when data gathering around 10¹⁷ cm⁻³ equal to Or less than the detection limit of the concentration of Si contaminant are classified into a group, the PVs represented by the respective data classified into the group are all distributed within a range which is not more than 30 nm like in FIG. 12. With this taken into consideration, it is desirable that the PV of the film should be set at 30 nm or less when a more exact reference is intended to be set up for the film.

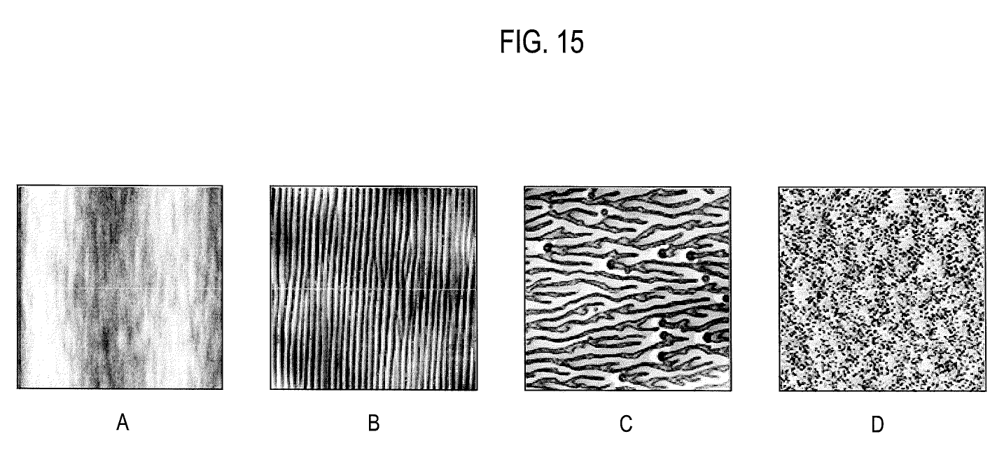

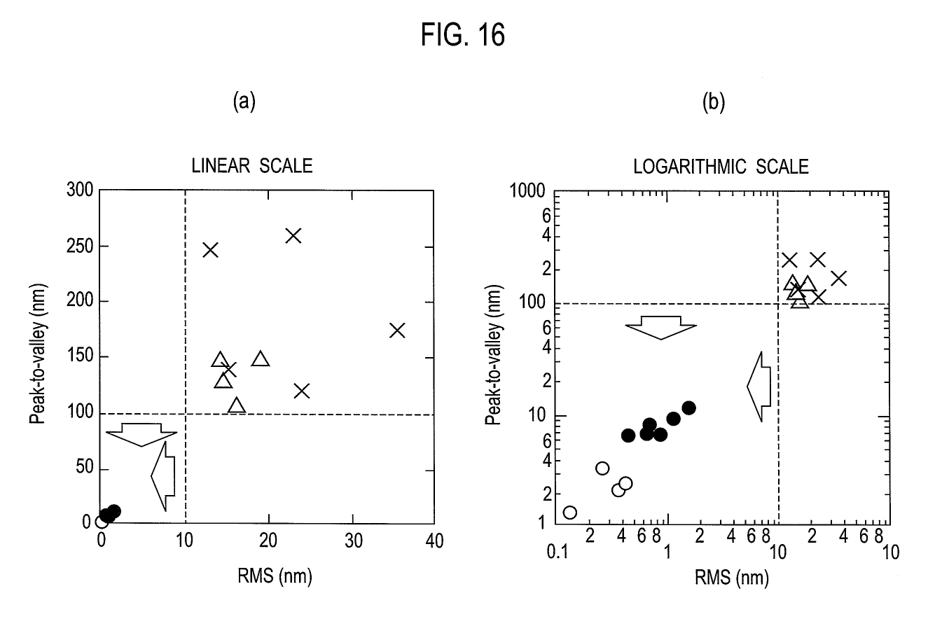

FIG. 15 show characteristic patterns typical of the surface shape of the surface of a MgZnO thin film, which were actually formed by changing the RMS and the PV. AFM images shown in FIG. 15 represent the characteristic patterns each in an area of 20 nm by 20 nm. Surface Shape A is termed as a “step and terrace structure.” The step height of the MgZnO thin film according to Surface Shape A is equal to the height of a single molecular layer. For this reason, the surface of the MgZnO thin film according to Surface Shape A has the most idealistic shape. It is a matter of course that the surface of the MgZnO thin film according to Surface Shape A is the flattest.

Surface Shape B is a step bunching surface. Basically, Surface Shape B belongs to the category of step and terrace structures. However, the step height of the MgZnO thin film according to Surface Shape B is higher than the height of a single molecular layer, and its steps are bunched together. For this reason, the surface of the MgZnO thin film according to Surface Shape B is termed as the “step bunching.” The surface of the MgZnO thin film according to Surface Shape B is seen to undulate more than the surface of the MgZnO thin film according to Surface Shape A when observed in a micro level. Yet, the surface of the MgZnO thin film according to Surface Shape B is classified as a “flat” surface from a macro point of view.

Surface Shapes C and D are shapes which fall outside the scope of the present invention, that is to say, surface shapes of the respective MgZnO thin films which satisfy RMS>10 nm or PV>100 nm. Surface Shape C is a surface shape similar to that which is often observed in an InGaN film. The surface of the MgZnO thin film according to Surface Shape C has a shape in which winding stripe-shaped islands are separated from one another by depressed portions each having its own rough surface. The surface of the MgZnO thin film according to Surface Shape D has a large number of pits, and is similar to a surface which is often observed in a ZnO film grown at a lower temperature.

FIG. 16 show RMS values and PV values which are classified into groups depending on the surface shapes. In FIG. 16, the horizontal axis represents RMS, and the vertical axis represents PV. Measured RMS values and measured PV values representing each of Surface Shapes A, B, C and D are plotted on graphs respectively shown in FIG. 16. ∘ (white circle), (black circle), x (cross) and Δ (white up-pointing triangle) respectively correspond to Surface Shape A, B, C and D. Furthermore, the vertical and horizontal axes in FIG. 16(a) use a linear scale, and the vertical and horizontal axes in FIG. 16(b) use a logarithmic scale.

As learned from FIG. 16, an existence area of RMS and PV data for Surface Shapes A and B, and an existence area thereof for Surface Shapes C and D are clearly separated from each other by a line representing PV=100 nm and a line representing RMS=10 nm. It has been already known that Surface Shapes A and B are suitable for semiconductor devices each obtained by stacking thin films one on another. As shown in FIGS. 16, 12 and 13, in order to prevent Si from being mixed into the thin film, the surface shape should be at least as flat as Surface Shapes A and B. From a viewpoint of the growth temperature, the growth temperature needs to be set at 800° C. or higher for the purpose of making the surface of the MgZnO thin film as suitably flat as Surface Shapes A and B, as described above. When the thin film is grown in this manner, Si can be excluded from the thin film.

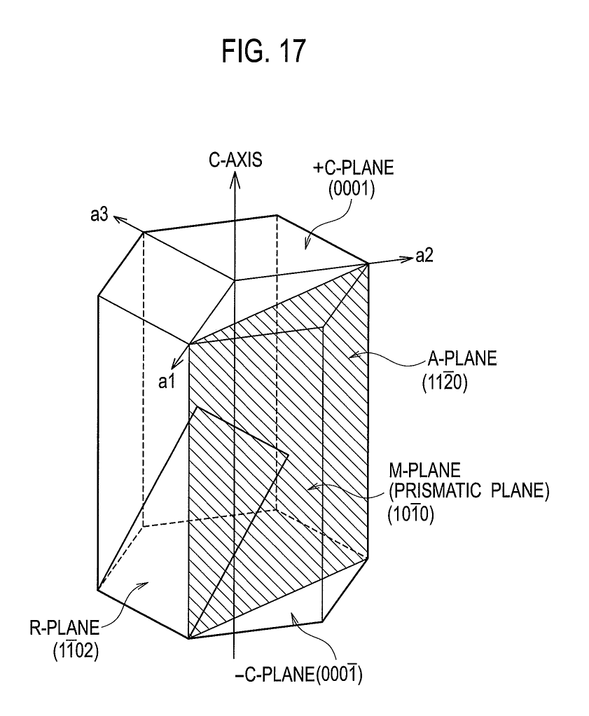

Let us examine a condition for flattening a film made of a ZnO-based compound from a viewpoint other than the viewpoint of the growth temperature, that is, from a viewpoint of a crystal structure. A substrate made of a ZnO-based compound such as Mg_{y}Zn_{1-y}O (0≦y<1) may be used as the substrate 1. Like gallium nitride (GaN), the ZnO-based compound has a hexagonal crystal structure as shown in FIG. 17, which is termed as the wurtzite structure. FIG. 17 is a schematic diagram showing a unit cell of the hexagonal crystal structure. A C-plane and an a-axis can be denoted by Miller indices. For example, the C-plane is denoted as the (0001) plane. In FIG. 17, a shaded plane is denoted as the A-plane (11-20), and an M-plane (10-10) is a prismatic plane of the hexagonal crystal structure. For example, the {11-20} plane is a generic notation denoting the set of all the planes which are equivalent to the (11-20) plane by the symmetry of the crystal lattice; and the {10-10} plane is a generic notation denoting the set of all the planes which are equivalent to the (10-10) plane by the symmetry of the crystal lattice. In addition, the a-axis is perpendicular to the A-plane; an m-axis is perpendicular to the M-plane; and a c-axis is perpendicular to the C-plane.

The substrate 1 made of Mg_{y}Zn_{1-y}O, which is used as a substrate for the crystal growth, may be a ZnO substrate which is made of ZnO containing no Mg when y=0 in Mg_{y}Zn_{1-y}O, or a MgZnO substrate which is made of a mixed crystal of ZnO and Mg. However, it is undesirable that the amount of Mg contained in the MgZnO substrate should exceed 50 wt % The reason for this is as follows. When the amount of Mg exceeds 50 wt %, MgO contained in the MgZnO substrate is apt to cause a phase separation between MgO and the ZnO-based compound, because the NaCl-type crystal structure of MgO makes it difficult to align the Zn-based compound having the hexagonal crystal system with MgO.

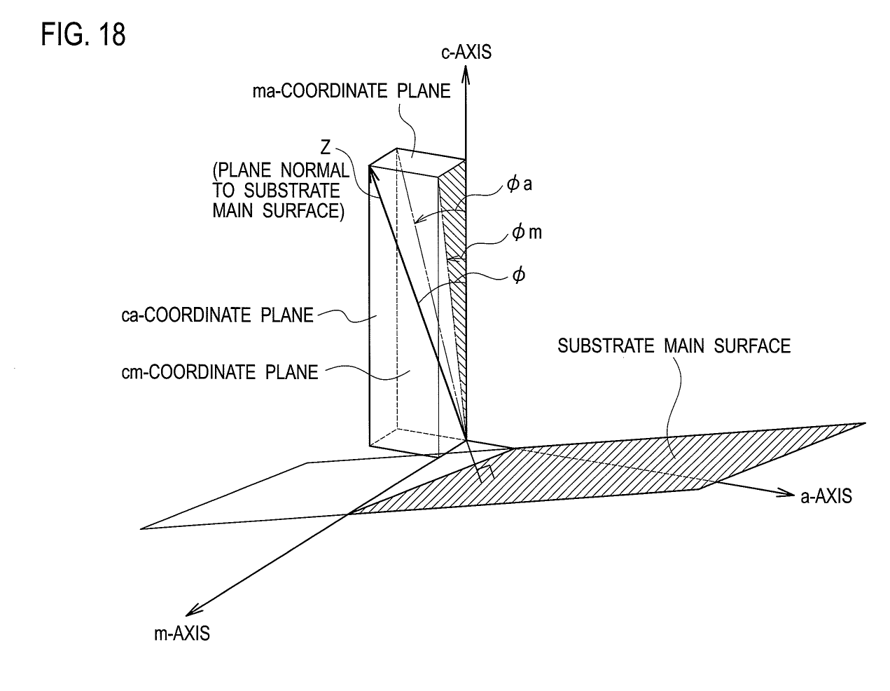

In addition, the main surface of the substrate 1 is defined, for example, as shown in FIG. 18. The normal Z to the substrate main surface 11 inclines at an angle Φ from the c-axis which is a substrate crystal axis. A projection axis, which is obtained by projecting the normal Z onto the cm-coordinate plane in the system of right-angled coordinates with the c-axis, m-axis and a-axis which are the substrate crystal axes, inclines to the m-axis at an angle of φm degrees. A projection axis, which is obtained by projecting the normal Z onto the ca-coordinate plane in the same system of right-angled coordinates, inclines to the a-axis at an angle of φa degrees.

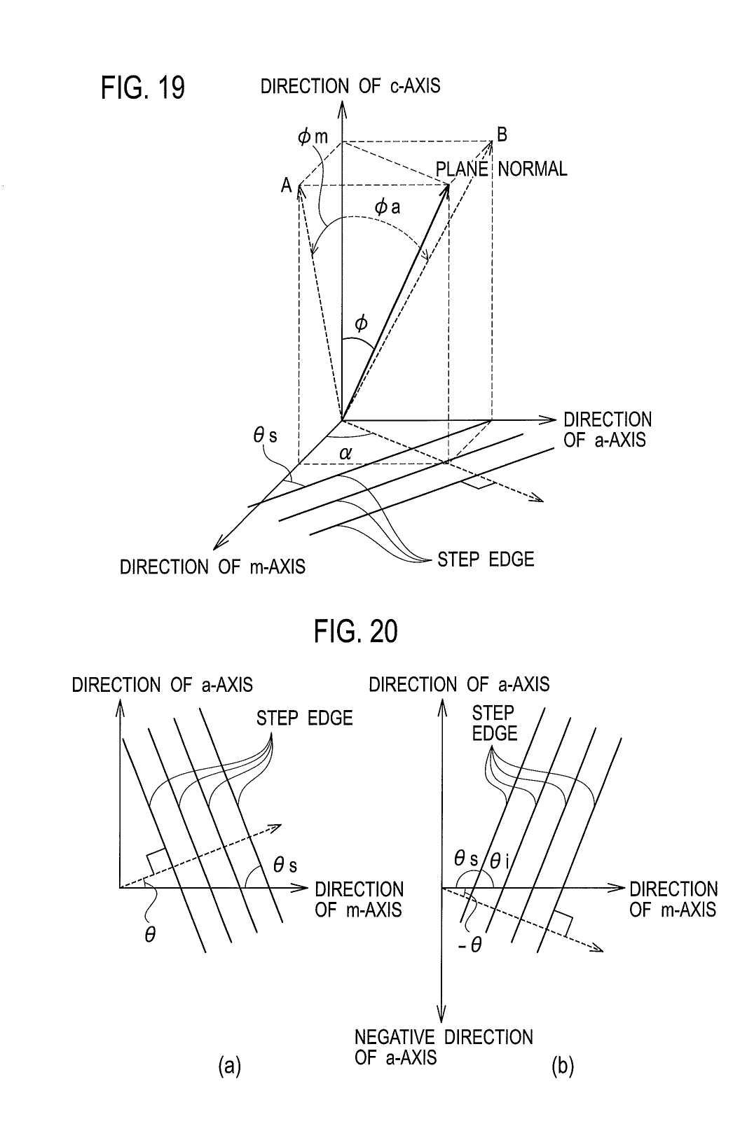

FIG. 19 is a diagram attempting to further clarify how the normal Z to the substrate main surface inclines as shown in FIG. 18 from a viewpoint of a relationship among the normal Z and the system of right-angled coordinates with the c-axis, m-axis and a-axis. What makes FIG. 19 look different from FIG. 18 is only the direction in which the normal Z to the substrate main surface inclines. What are denoted by φm and φa in FIG. 19 are the same as those which are denoted by φm and φa in FIG. 18. Furthermore, FIG. 19 illustrates: a projection axis A obtained by projecting the normal Z, which is normal to the substrate main surface, onto the cm-coordinate plane in the system of right-angled coordinates with the c-axis, m-axis and a-axis; and a projection axis B obtained by projecting the normal Z onto the ca-coordinate plane in the same system of right-angled coordinates.

The substrate 1 is polished in a way that the substrate main surface 11 is a surface which inclines at least toward the m-axis as shown in FIG. 19. In FIG. 19, φ denotes an angle between a direction of the c-axis and a direction of a plane normal to the substrate main surface 11 (the normal Z to the substrate main surface); φm degrees represents an angle between the direction of the c-axis and the projection axis A obtained by projecting the plane normal, which is normal to the substrate main surface 11, onto the mc-coordinate plane defined by the m-axis and c-axis which are substrate crystal axes (the angle will be hereinafter referred to as an “m-axis component of the angle of the inclination of the plane normal”); and pa degrees represents an angle between the direction of the c-axis and the projection axis B obtained by projecting the plane normal, which is normal to the substrate main surface 11, onto the ac-coordinate plane defined by the a-axis and c-axis which are substrate crystal axes (the angle will be hereinafter referred to as an “a-axis component of the angle of inclination of the plane normal”).

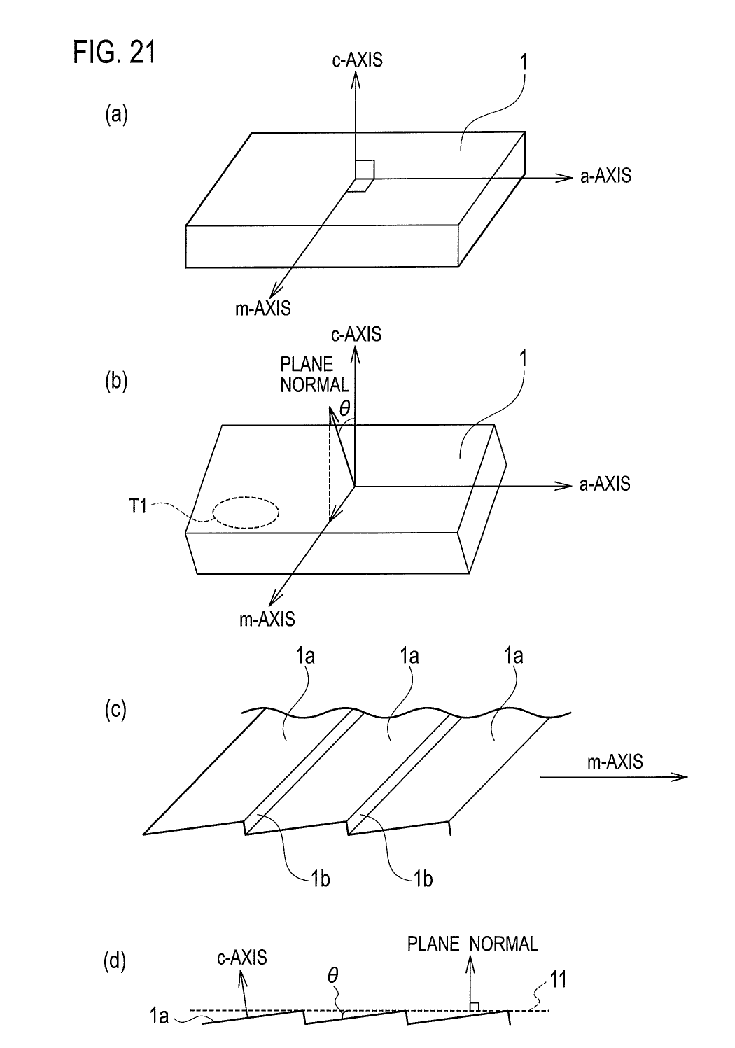

In this respect, descriptions will be provided for why the plane normal to the substrate main surface 11 is caused to incline toward the m-axis. FIG. 21(a) shows a schematic diagram of a substrate in which the plane normal to the surface main surface 11 inclines to neither the a-axis nor the m-axis. In other words, FIG. 21(a) shows the schematic diagram of the substrate in which the direction of the plane normal to the substrate main surface 11 coincides with the direction of the c-axis.

In a case of a bulk crystal, however, the direction of the plane normal to the substrate main surface 11 does not coincide with the direction of the c-axis unlike shown in FIG. 21(a), if no cleavage plane of the bulk crystal is used. Accordingly, as long as the substrate whose main surface exactly coincides with the C-plane is insistently produced, the insistence decreases the productivity. In reality, the direction of the plane normal to the substrate main surface 11 inclines from the c-axis at an off angle. For example, when the direction of the plane normal to the substrate main surface 11 inclines only toward them-axis from the c-axis at an angle of θ degrees as shown in FIG. 21(b), terrace surfaces 1a and step surfaces 1b are produced in the substrate main surface 11 as shown in FIG. 21(c) which is a magnified view of the substrate main surface 11 (for example, an T1 area). In this respect, the terrace surfaces 1a are flat surfaces. The step surfaces 1b are those that regularly occur in the respective step portions, which are caused when the plane normal inclines from the c-axis, at equal intervals.

In this substrate main surface 11, the terrace surfaces 1a are the C-planes (0001), and the step surfaces 1b correspond to the M-planes (10-10). As shown in FIG. 21(c), the step surfaces 1b lie one after another regularly in the direction of the m-axis while a space corresponding to the width of each terrace 1a is interposed between each two neighboring step surfaces 1b. In other words, each terrace surface 1a inclines from the substrate main surface 11, and the angle of inclination of the terrace surface 1a is the θ degrees.

The condition of the main surface, which is shown in FIG. 21(c), corresponds to the condition of the main surface which is shown in FIGS. 19 and 20 where θs=90°. Note that “step edges” shown in FIGS. 19 and 20 are projections of the step portions, which are caused by the step surfaces 1b, onto the ma-coordinate plane defined by the m-axis and the a-axis. Each atom, which impinges against any one step portion caused by the corresponding step surface 1b in the substrate main surface 11, is bound to two surfaces which include the step surface 1b and either of the two terrace surfaces 1a contiguous to the step surface 1b. For this reason, atoms impinging against the step surfaces 1b are bound to the substrate main surface 11 stronger than atoms impinging against the terrace surfaces 1a. Accordingly, the step surfaces 1b can stably trap atoms which impinge against the step surface 1b.

In other words, a stable crystal growth is achieved through a lateral growth process in the step portions each having the stronger bonding force together with a surface diffusion process in the terrace surfaces 1a. In this respect, the surface diffusion process is that in which atoms impinging against the terrace surfaces 1a are diffused into the terrace surfaces 1a. The lateral growth process is that in which: atoms impinging against the step portions are trapped by the step portions and kink locations which are formed in the step portions; and the thus-trapped atoms are accordingly incorporated in the crystal. When a ZnO-based semiconductor layer is deposited on the substrate in which the plane normal to the substrate main surface 11 inclines at least toward the m-axis as described above, the deposited ZnO-based semiconductor layer can be formed into a flat film because the crystal of the ZnO-based layer is grown mainly in the step surfaces 1b. When the substrate is arranged in a way that the step surfaces 1b correspond to the M-plane, the semiconductor layer 2 made of the ZnO-based semiconductor, whose crystal is grown on the substrate main surface 11, can be formed into a film whose main surface 21 is flat.

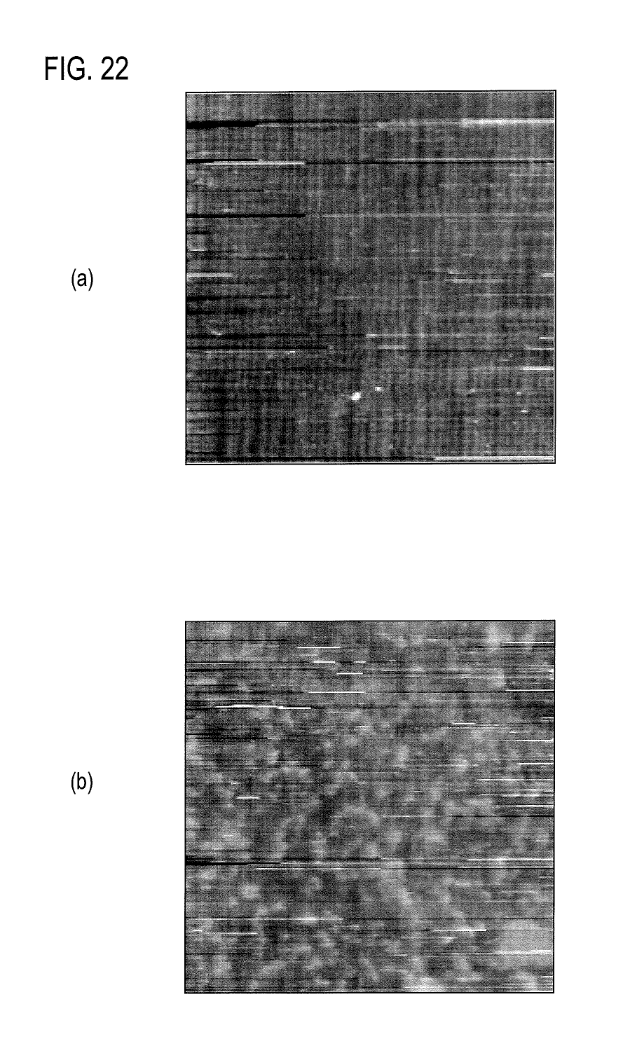

Note that, if the angle θ of inclination defined in FIG. 21(b) is set too large, the crystal of the ZnO-based semiconductor layer is not flatly grown on the substrate main surface 11. FIG. 22 show how the flatness of the semiconductor film on the substrate main surface 11 changes depending on the angle θ of the inclination toward the m-axis. FIG. 21(a) shows a condition of the main surface 21 of the ZnO-based semiconductor layer 2 which was grown on the substrate main surface 11 of the Mg_{y}Zn_{1-y}O substrate 1 in which the plane normal to the substrate surface 11 inclines toward m-axis at an angle of 1.5°. FIG. 21(b) shows a condition of the main surface 21 of the ZnO-based semiconductor layer 2 which was grown on the substrate main surface 11 of the Mg_{y}Zn_{1-y}O substrate 1 in which the plane normal to the substrate surface 11 inclines toward m-axis at an angle of 3.5°. FIGS. 21(a) and 21(b) are images which were obtained by scanning the respective main surfaces 21 in a field of view of 1 μm by 1 μm with the atomic force microscope after their crystals were grown. The main surface 21 shown in FIG. 21(a) is formed flat with the widths of the respective steps being equal to one another. In contrast, the main surface 21 shown in FIG. 21(b) is not flat with depressions and protrusions being dispersed in the main surface 21. With this taken into consideration, it is desirable that the φm degrees representing the component of the angle of the inclination, which is shown in FIG. 19, should be set at an angle which exceeds 0° but not 3° (0°<φm≦3°).

As described above, it is desirable that: the substrate main surface 11 should be caused to incline only toward the m-axis; and the φm degrees representing the component of the angle of the inclination should be set at an angle which exceeds 0° but not 3°. In reality, however, it is difficult for the substrate to be cut out of an ingot with the substrate main surface 11 being caused to incline only toward the m-axis. From a viewpoint of the production technology, the substrate main surface 11 needs to be allowed to incline toward the a-axis as well. Accordingly, it is necessary to specify how much the substrate main surface 11 should be allowed to incline toward the a-axis. For example, as shown in FIG. 19, the direction of the plane normal to the substrate main surface 11 may incline from the c-axis in away that the direction has the φm degrees representing the m-axis component of the angle of the inclination and the φa degrees representing the a-axis component of the angle of the inclination. In other words, the substrate main surface 11 may be made in a way that the substrate main surface 11 inclines toward the m-axis at the φm degrees and toward the a-axis at the φa degrees.

In this respect, an angle θs between the step edge of each step surface 1b and the direction of the m-axis needs to fall within a certain range. In other words, the step edges need to be caused to lie one after another regularly in the direction of the m-axis for the purpose of growing the semiconductor layer 2 whose main surface 21 is flat. If the intervals at which the step edges lie one after another and the lines of the respective step edges are in disorder, the lateral growth is obstructed. This obstruction makes it impossible to form the semiconductor layer 2 whose main surface 21 is flat. Hereinafter, a possible range of the angle θs will be described.

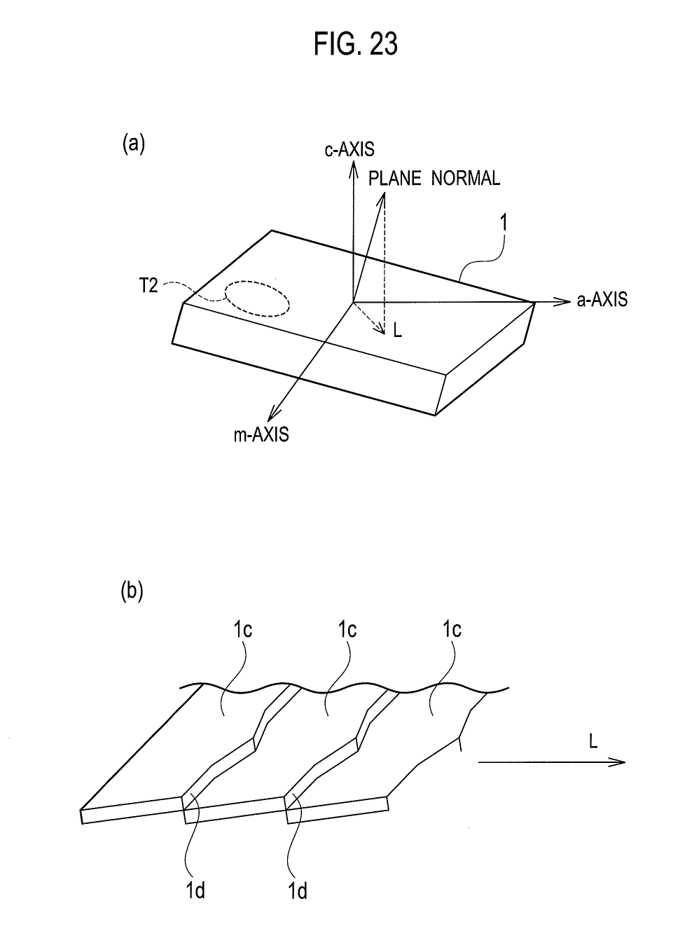

FIG. 23(a) schematically shows the plane normal to the substrate main surface 11 which inclines toward both the m-axis and the a-axis as shown in FIG. 19. As shown in FIG. 23(a), a direction, in which a projection axis obtained by projecting the plane normal to the substrate main surface 11 onto the ma-coordinate plane extends, is denoted as an L direction. In addition, FIG. 23(b) shows a magnified view of a part (for example, a T2 area) of the substrate main surface 11. Terrace surfaces 1c and step surfaces 1d are produced in the substrate main surface 11. In this respect, the terrace surfaces 1c are flat surfaces, and the step surfaces 1d are those that occur in the respective step portions, which are caused when the substrate main surface 11 inclines from the c-axis. Each terrace surface 1c is the C-plane (0001). None of the terrace surfaces 1c are in parallel to the substrate main surface 11. Accordingly, the terrace surfaces 1c are those which incline from the substrate main surface 11. This means that the c-axis, which is perpendicular to each terrace surface 1c, inclines from the plane normal to the substrate main surface 11 at the φ degrees, when the notation system shown in FIG. 19 is used.

Because the substrate main surface 11 inclines toward not only the m-axis but also the a-axis, the step surfaces 1d are produced diagonally in away that the step surfaces 1d lie one after another in the L direction as shown in FIG. 23(b). When the step surfaces 1d are in this condition, their step edges lie one after another in the direction of the m-axis as shown in FIGS. 19 and 20. Because the M-plane is thermally and chemically stable, it is likely that each diagonal step may not be kept in good shape depending on the size of the φa degrees which represents the a-axis component of the angle of the inclination. For example, as shown in FIG. 23(b), the step surfaces 1d present a wavy appearance, and the arrangement of the step edges is in disorder. This makes it impossible to form a film, whose main surface is flat, on the substrate main surface 11.

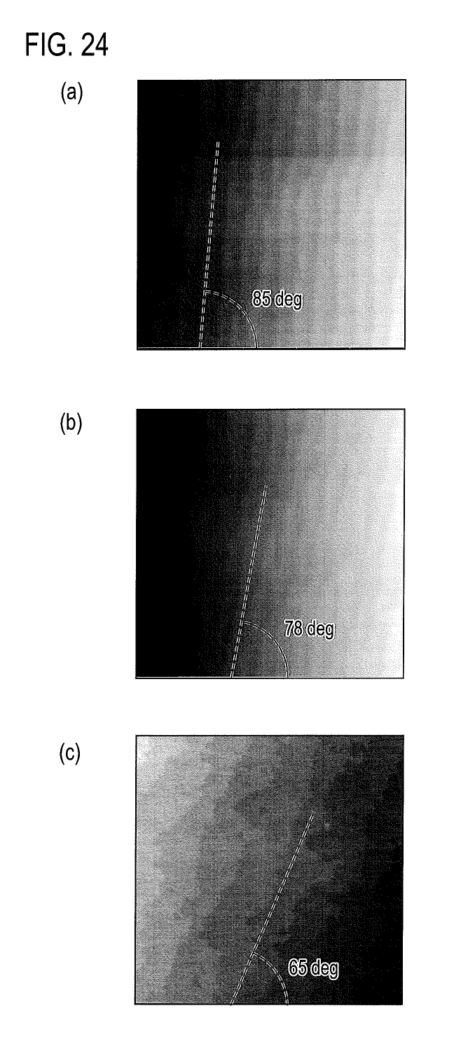

FIG. 24 show how the step edges and the step widths change in a case where the substrate main surface 11 (growth surface) has an off angle to the a-axis (the φa degrees representing the component of the angle of the inclination) in addition to an off angle to the m-axis (the φm degrees representing the component of the angle of the inclination). A comparison was made in terms of the step edges and the step widths among the substrate main surfaces which were obtained by changing the φa degrees representing the a-axis component of the angle of the inclination while the φm degrees representing the m-axis component of the angle of the inclination, which has been explained in relation to FIG. 19, was fixed at 0.4°. The change in the φa degrees representing the a-axis component of the angle of the inclination was achieved by changing the slice surface of the Mg_{y}Zn_{1-y}O substrate 1.

As the φa degrees, which represented the a-axis component of the angle of the inclination, was changed in a way that the φa degrees increased, the angle θs between the step edges and the direction of the m-axis changed in a way that the angle θs increased as well. With this taken into consideration, numeric values representing the angle θs were shown in FIG. 24, respectively. FIG. 24(a) shows the step edges and the step widths which were observed when θ=85°. It was confirmed that both the step edges and the step widths were in order. FIG. 24(b) shows the step edges and the step widths which were observed when θs=78°. Although the step edges and the step widths were slightly out of order, both the step edges and the step widths were still recognizable. FIG. 24(c) shows the step edges and the step widths which were observed when θs=65°. Both the step edges and the step widths went out of order, and none of the step edges nor the step widths were recognizable. When the ZnO-based semiconductor layer is epitaxially grown on the substrate main surface 11 whose surface condition is as shown in FIG. 24(c) the surface of the thus-made ZnO-based semiconductor layer is poor in flatness. In the case shown in FIG. 24(c), 65° representing the angle θs corresponds to 0.15° representing the a-axis component φa of the angle of the inclination when converting the angle θs into an equivalent of the a-axis component φa of the angle of the inclination. On the basis of these data, it is clear that the angle θs is desirably set in a range of 70°≦θs≦90° for the purpose of forming the semiconductor layer 2 on the substrate main surface 11 in a way that the main surface 21 has a good flatness.

Note that the angle θs needs to be examined not only in the case where the plane normal to the substrate main surface 11 inclines to the positive direction of the a-axis at the φa degrees representing the component of the angle of the inclination, but also in the case where the plane normal to the substrate main surface 11 inclines to the negative direction of the a-axis in FIG. 19. That is because, by the symmetry, the inclination of the plane normal to the substrate main surface 11 to the negative direction of the a-axis is equivalent to the inclination of the plane normal to the substrate main surface 11 to the positive direction of the a-axis at φₐ degrees representing the component of the angle of the inclination. When the step portions caused by the respective step surfaces are projected onto the ma-coordinate plane with this component of the angle of the inclination being defined as −φₐ degrees, the step edges and the step widths are represented as shown in FIG. 20(b). In this respect, like the condition imposed on the angle θs, the condition imposed on the angle θi between the direction of the m-axis and the step edges can satisfy 70°≦θi≦90°. Because θs=180°-θi, the maximum value of θs is 110° which results from 180°-70°. Eventually, the range of 70°≦θs≦110° becomes the condition for forming the semiconductor layer 2, whose main surface 21 is flat, on the substrate main surface 11.

An angle α shown in FIG. 19 represents an angle between the direction of the c-axis and a projection axis obtained by projecting the plane normal, which is normal to the substrate main surface 11, onto the ma-coordinate plane. The angle α is given by Equation (1) as follows.

α=(180/Π)arctan {tan(Πφₐ/180)/tan(Πφm/180)} (1)

where: a unit of measure for the angle α, the component φm of the angle of the inclination, and the component φa of the angle of the inclination is degree (deg); tan is the abbreviation of the tangent; and arctan is the abbreviation of the arctangent. When the angle θs, whose unit of measure is degree, is expressed by use of the component φm of the angle of the inclination and the component φa of the angle of the inclination on the basis of FIG. 19, the angle θs is given by Equation (2) as follows.

$$\begin{matrix}θ s = 90 - α \\ = 90 - ( 180 / Π ) arctan \{ tan ( {Πϕ}_{a} / 180 ) / tan ( Πϕ m / 180 ) \}\end{matrix} \qquad ( 2 )$$

From Equation (2), Equation (3) expressed with

70≦90−(180/Π)arctan {tan(Πφₐ/180)/tan(Πφm/180)}≦110 (3)

is obtained as a desirable range of the angle θs for forming the semiconductor layer 2, whose main surface 21 is flat, on the substrate main surface 11. When θs=90 degrees, the plane normal to the substrate main surface 11 inclines only toward the m-axis, but not toward the a-axis.

As already described above, it is desirable that φm should satisfy 0°<φm≦3° from the viewpoint that the main surface 21 of the semiconductor layer 2 needs to be kept flat for the purpose of inhibiting the semiconductor layer from being doped with the unintentional acceptor. Accordingly, a desirable range of the φa degrees representing the component of the angle of the inclination can be calculated from the Equation (3) for determining the φm degrees representing the component of the angle of the inclination.

Descriptions will be provided for a method of manufacturing the semiconductor device shown in FIG. 1 by use of the thin film forming apparatus shown in FIG. 2. Note that the method of manufacturing a semiconductor device, which will be described below, is only an example. It is a matter of course that the method of manufacturing the semiconductor device can be implemented by various other manufacturing methods including this modified example. Note that it is desirable that the substrate 1, which will be described hereinafter, should be the ZnO-based substrate which satisfies the following condition. As described above, the angle between the direction of the c-axis and the projection axis obtained by projecting the plane normal to the substrate main surface 11 onto the ac-coordinate plane (the φₐ degrees representing the component of the angle of the inclination) should be equal to or less than 0.1°; and the angle between the direction of the c-axis and the projection axis obtained by projecting the plane normal to the substrate main surface 11 onto the mc-coordinate plane (the φm degrees representing the component of the angle of the inclination) should be equal to or less than larger than 3°. Otherwise, it is desirable that the substrate 1 should be a substrate which makes the φa degrees representing the component of the angle of the inclination and the φm degrees representing the component of the angle of the inclination satisfy Equation (3).

(1) The substrate 1 whose main surface is the +C-plane, and which is made of, for example, ZnO, is etched with a hydrochloric acid. Subsequently, the thus-etched substrate 1 is cleansed with pure water. Thereafter, the resultant substrate 1 is dried with dry nitrogen.

(2) As shown in FIG. 2, the substrate 1 set on the holder 110 is introduced into the thin film forming apparatus used for the MBE method through the load-lock chamber.

(3) The substrate 1 is heated at 900° C. in vacuum of approximately 1×10⁻⁷ Pa for 30 minutes.

(4) The substrate temperature is decreased to 900° C. A NO gas and an O₂ gas are supplied, and plasma is thus generated. The plasma is supplied along with Mg and Zn which are beforehand controlled to make a desired composition. Thereby, the semiconductor layer 2 made of MgₓZn₁₋ₓO is grown on the substrate 1. Thereafter, the semiconductor layer 2 is doped with an acceptor such as nitrogen.

What is important as conditions for manufacturing the semiconductor layer 2 is the substrate temperature. As already described above, when the main surface 21 of the semiconductor layer 2 is flat as in the case of Sample A, the semiconductor layer 2 is not doped with Si and the like which are dislodged from the discharge tube 131 due to the sputtering phenomenon. Judging from the fact that nitrogen enters easily the +C-plane of the hexagonal crystal system, one may consider that the +C-plane has a mechanism of rejecting cations (ions working like a cathode) (for example, a mechanism which makes polarized charges positive in the +C-plane). With this taken into consideration, the substrate temperature needs to be equal to or higher than 750° C. In the case of MgₓZn₁₋ₓO, this lower limit temperature tends to rise. When the substrate temperature is 800° C., the semiconductor layer 2, which is made of MgₓZn₁₋ₓO in whose composition a proportion of Mg is approximately 20% at maximum, can keeps its flatness. It is a matter of course that the surface temperature may be arbitrarily set at a temperature which enables the main surface 21 to be kept flat.

Note that: the temperature of the substrate 1 may be measured by use of a pyrometer with a Ti/Pt piece being attached to the back surface of the substrate 1: otherwise, the temperature thereof may be measured by a thermoviewer. Each temperature, which has been shown above, represents a value obtained by performing the temperature measurement with ε=0.18 when the pyrometer was used, or with ε=0.71 when the thermoviewer was used. In a case where a thermoviewer is used while the thin film is grown, the thin film forming apparatus requires an arrangement. To put it concretely, the thin film forming apparatus uses a viewport made of barium fluoride (BaF₂) as a window material, instead of a viewport made of glass or quartz which are usually used for the thin film forming apparatus. That is because the viewport made of glass or quartz does not transmit a measured wavelength in a wave range of 8 to 14 μm. The apparatus equipped with the viewport made of barium fluoride is suitable for measuring the substrate temperature because of the following reasons: long-wave infrared light can pass the viewport; and a risk of measuring a temperature which radiates from an object behind the substrate 1 is small since the transmittance of ZnO is lower in this wavelength range. The substrate temperature measured with any device other than the pyrometer or thermoviewer (with a thermocouple of a heater or the like) is unsuitable for measuring the substrate temperature, because such a device does not necessarily measure the substrate itself.

As described above, the present invention clarifies the conditions which are imposed on the semiconductor device for the purpose of inhibiting the semiconductor layer 2 from being unintentionally doped with Si and the like. In the case of the semiconductor device shown in FIG. 1, when the main surface 21 of the semiconductor layer 2 is observed with the atomic force microscope, the density of observable hexagonal pits 201 is not more than 5×10⁶ atoms/cm². Otherwise, no depressed portion 202, which includes multiple microcrystalline protrusions formed in the bottom portion of the depressed portion, is found in the main surface 21. Furthermore, the substrate 1 is chosen to be used from the viewpoint that the inclination of the substrate main surface 11 to the a-axis direction and the m-axis direction satisfies the condition the main surface 21 of the semiconductor layer 2 grown on the substrate main surface 11 should be formed flat. Consequently, the foregoing RMS roughness and PV fall within the predetermined scopes, and it is accordingly to form the flat film. Because the flat main surface 21 whose surface roughness is inhibited can be made, it is possible to inhibit the semiconductor layer 2 from being doped with the unintentional impurities. This makes it easy to dope the semiconductor layer 2 with the acceptor such as nitrogen, and accordingly to make the MgₓZn₁₋ₓO semiconductor layer 2 into the p-type semiconductor layer.

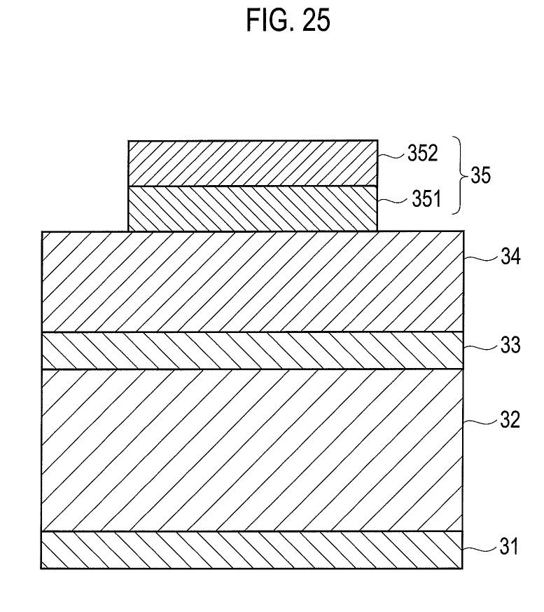

Finally, FIG. 25 shows an example of an ultraviolet LED using a film made of MgₓZn₁₋ₓO (0≦x<1) containing the p-type impurity which is produced under the foregoing conditions. A ZnO substrate 32 was formed in a way that: the main surface of the ZnO substrate 32, which included the +C-plane, was chosen as the crystal growth surface; and a direction of the normal to the main surface inclined slightly toward the m-plane from the C-plane. The crystal of an undoped ZnO layer 33 and the crystal of a nitrogen-doped p-type MgZnO layer 34 were sequentially grown on the ZnO substrate 32. Thereafter, a p-electrode 35 and an n-electrode were formed thereon. As illustrated, the p-electrode was constituted of a multilayered metal film made of Au (gold) 352 and Ni (nickel) 351, and the n-electrode 31 was made of In (indium). The nitrogen-doped MgZnO layer 34 was the ZnO-based thin film according to the present invention. The nitrogen-doped MgZnO layer 34 was produced at a growth temperature of approximately 800° C. in a way that: the RMS roughness as one of the surface roughness indices was not more than 10 nm; and the PV as the other of the surface roughness indices was not more than 100 nm. After the ultraviolet LED was produced in this manner, a PL (photoluminescence) light emission and an EL (electroluminescence) light emission from the ultraviolet LED were measured.

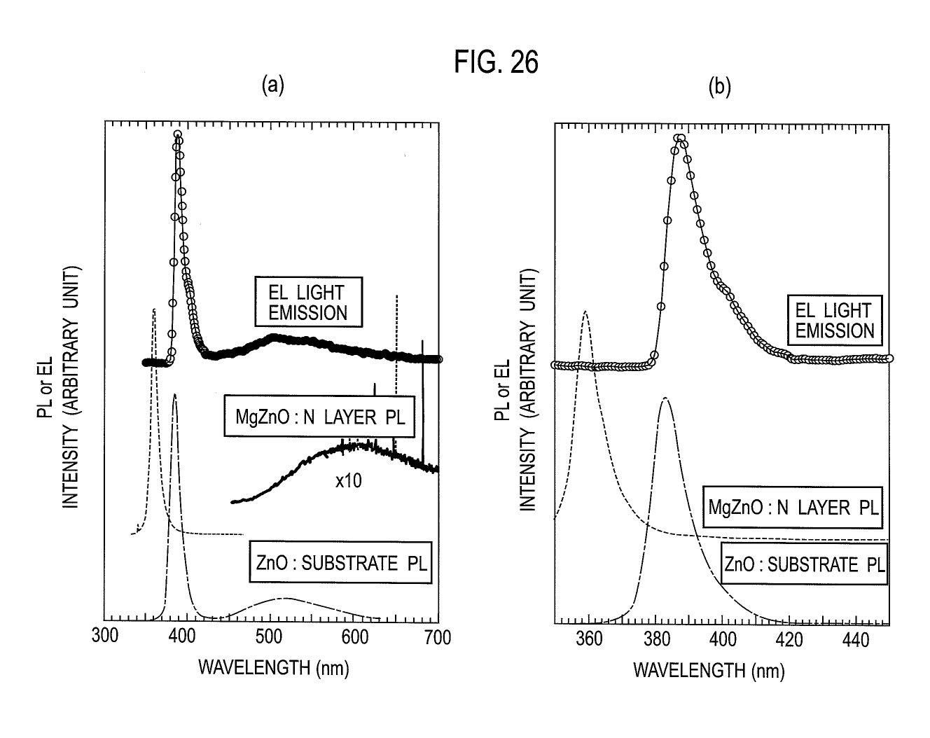

FIG. 26(a) shows the spectral distributions of the PL light emission and the EL light emission in a wavelength range of 300 nm to 700 nm. FIG. 23(b) shows the spectral distributions of the PL light emission and the EL light emission by magnifying their wavelength ranges of 350 nm to 450 nm. The spectrum in the EL light emission was almost the same as that in the PL light emission from ZnO. In addition, the EL light emission lacked light emission in and around a wavelength of 630 nm which is typical of the nitrogen-doped MgZnO layer 34. This indicated that: holes were injected from the nitrogen-doped MgZnO layer 34; and no electrons leaked from the undoped ZnO layer 33 to the nitrogen-doped MgZnO layer 34. From this, it is clear that: the present invention prevented Si from being taken into the nitrogen-doped MgZnO layer 34; and the p-type conduction was not obstructed.

The present invention has been described on the basis of the foregoing embodiment. However, the present invention is not limited by any portion of the descriptions and drawings which constitute a part of this disclosure. From this disclosure, various alternative embodiments, examples and operational technologies will be apparent to those skilled in this art. In other words, it is a matter of course that the present invention includes various embodiments and the like which have not been described herein. For this reason, the technological scope of the present invention shall be determined only by the matter to define the invention according to the scope of claims which are reasonably understood from the foregoing descriptions.

1. A ZnO-based thin film formed of MgₓZn₁₋ₓO (0≦x<1) containing a p-type impurity,
the ZnO-based thin film comprising a main surface which satisfies at least one of the following conditions when the main surface is observed with an atomic force microscope:
the density of observed hexagonal pits is not more than 5×10⁶ pits/cm²; and
no depressed portion, which includes a plurality of microcrystalline protrusions formed in a bottom portion of the depressed portion, is observed.

2. The ZnO-based thin film according to claim 1, wherein the p-type impurity is nitrogen.

3. The ZnO-based thin film according to claim 1, wherein
the MgₓZn₁₋ₓO thin film is formed by crystal growth on a ZnO substrate whose main surface on a crystal growth side has a c-plane.

4. The ZnO-based thin film according to claim 1, wherein
each pit is a defect including a hexagonal crystal plane when viewed from above, and a cross-section of the pit looks like a funnel.

5. A semiconductor device comprising the ZnO-based thin film according to claim 1.

6. A semiconductor device comprising:
a ZnO-based thin film formed of MgₓZn₁₋ₓO (0≦x<1) containing a p-type impurity, the Zn-based thin film including a main surface which satisfies at least one of the following conditions when the main surface is observed with an atomic force microscope: the density of observed hexagonal pits is not more than 5×10⁶ pits/cm²; and no depressed portion, which includes a plurality of microcrystalline protrusions formed in a bottom portion of the depressed portion, is observed; and
a substrate formed of Mg_{y}Zn_{1-y}O (0≦y<1), the substrate including a substrate main surface in contact with the ZnO-based thin film, wherein
a projection axis in the substrate, which is obtained by projecting a normal line of the substrate main surface on plane produced by a m-axis and a c-axis of a substrate crystal axis as its bases, inclines toward an m-axis at an angle of 3 degrees or less.

7. The semiconductor device according to claim 6, wherein
a projection axis, which is obtained by projecting the normal line of the substrate main surface on plane produced by an a-axis and a c-axis of a substrate crystal axis as its bases, inclines toward an a-axis at an angle of φa degrees,
a projection axis, which is obtained by projecting the normal line of the substrate main surface on plane produced by a m-axis and a c-axis of a substrate crystal axis as its bases, inclines toward the m-axis at an angle of φm degrees, and
φa and φm satisfy a relationship expressed by
70≦90−(180/Π)arctan {tan(Πφa/180)/tan(Πφm/180)}≦110.
